(19) United States
(12) Patent Application Publication
(10) Pub. No.: US 2025/0030427 A1
(43) Pub. Date: Jan. 23, 2025

(54) CIRCUIT WITH A PHASE LOCKED LOOP WITH DISTURBANCE RESPONSES

(71) Applicant: TEXAS INSTRUMENTS INCORPORATED, Dallas, TX (US)

(72) Inventors: Marius Moe, FETSUND (NO); Hagen Graf, OSLO (NO); Tarjei Aaberge, NESOYA (NO)

(21) Appl. No.: 18/524,711

(22) Filed: Nov. 30, 2023

Related U.S. Application Data
(60) Provisional application No. 63/527,429, filed on Jul. 18, 2023.

(51) Int. Cl. H03L 7/093; H03L 7/089; H03L 7/099

(52) U.S. Cl. CPC H03L 7/093; H03L 7/0891; H03L 7/0991

(57) ABSTRACT

A circuit for a phase-locked loop is described herein. The circuit includes a phase frequency detector configured to determine a phase error, a loop filter coupled to the phase frequency detector and configured to provide a clock control signal based on the phase error, and a controller coupled to the phase frequency detector and to the loop filter. The controller is configured to receive the phase error, detect a behavior of the phase error, and, responsive to the behavior of the phase error, perform a response that includes causing the phase frequency detector to adjust the phase error and causing the loop filter to adjust the clock control signal. Thus, the circuit may reduce settling time, overshoot, and/or undershoot in an output clock generated based on the clock control signal.

### CROSS-REFERENCE TO RELATED APPLICATIONS

This application claims priority to U.S. Provisional Application No. 63/527,429,filed Jul. 18, 2023, which is hereby incorporated by reference.

### TECHNICAL FIELD

Examples of the present disclosure generally relate to phase-locked loops and, in particular, to a circuit with a phase-locked loop that has one or more responses configured to handle disturbances, such as step responses, to settle the phase-locked loop faster.

### BACKGROUND

A phase-locked loop (PLL) is a circuit that generates an output signal whose phase and frequency are related to those of an input signal. An example PLL receives a reference clock as an input signal and generates an output clock as an output signal. Some PLLs, such as a radio frequency (RF) PLL, may encounter events, such as phase acquisition (going from open-loop to closed-loop operation) and sudden changes in inputs or outputs (e.g., step responses, sudden presence of power amplifier pulling), that tend to hinder the ability of the PLL to lock or hold the output signal in relation to the input signal.

### SUMMARY

A circuit for a phase-locked loop is described herein. The circuit includes a phase frequency detector configured to determine a phase error, a loop filter coupled to the phase frequency detector and configured to provide a clock control signal based on the phase error, and a controller coupled to the phase frequency detector and to the loop filter. The controller is configured to receive the phase error, detect a behavior of the phase error, and, responsive to the behavior of the phase error, perform a response that includes causing the phase frequency detector to adjust the phase error and causing the loop filter to adjust the clock control signal. Thus, the circuit may reduce settling time, overshoot, and/or undershoot in an output clock generated based on the clock control signal.

A circuit is described herein that includes a phase locked loop circuit that, in turn, includes: a phase frequency detector configured to receive a reference clock and a feedback clock and determine a phase error based on the reference clock and the feedback clock, a loop filter coupled to the phase frequency detector and configured to provide a clock control signal based on the phase error, and an oscillator coupled to the loop filter and configured to provide a clock signal based on the clock control signal. The feedback clock is based on the clock signal, and the phase locked loop circuit is configured to provide an output clock based on the clock signal. The circuit also includes a controller coupled to the phase locked loop circuit that is configured to receive the phase error, detect a behavior of the phase error, and responsive to the behavior of the phase error, perform a response that includes causing the phase frequency detector to adjust the phase error and causing the loop filter to adjust the clock control signal.

A method for a phase-locked loop is described herein. The method includes receiving a phase error with respect to a reference clock and a feedback clock. The phase error is determined by a phase frequency detector, and the feedback clock is generated based on an output of a loop filter. The method further includes detecting whether a behavior of the phase error is present and, based on whether the behavior is present, determine whether to perform a response that includes causing the phase frequency detector to adjust the phase error and causing the loop filter to adjust the output of the loop filter.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a block diagram of an example circuit that includes a phase-locked loop, according to some examples.

FIG. 2 is a flow diagram of a method that may be performed by a circuit that includes a phase-locked loop, according to some examples.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Some PLLs, such as a radio frequency (RF) PLLs, may encounter disturbances, such as phase acquisition and rapid changes in inputs or outputs (e.g., step change in wanted output frequency, sudden presence of power amplifier pulling). that may hinder the ability of the PLL to establish and maintain a fixed relationship between an input signal and an output signal. Several controllable factors decide the PLL response to these events, such as loop bandwidth and damping factor. In some cases, to reduce settling time, PLLs initially use higher loop bandwidth followed by one or more loop bandwidth reductions to reach the desired PLL performance.

Additionally or in the alternative, some of the examples disclosed here are directed to a PLL circuit configured to respond to disturbances in a manner that improves transient settling time by, for example, reducing the amplitude of output frequency undershoot and overshoot beyond that which can be achieved by adjusting loop bandwidth alone. To achieve this, some PLL circuits disclosed herein can implement one or more different PLL responses using non-linear operations when a disturbance is encountered. Based on which response is selected, an example circuit can respond to unwanted PLL behavior by wrapping the current phase error (e.g., adjusting the current phase to be with a narrow range), re-initializing the phase error, or maintaining a current operation of the PLL.

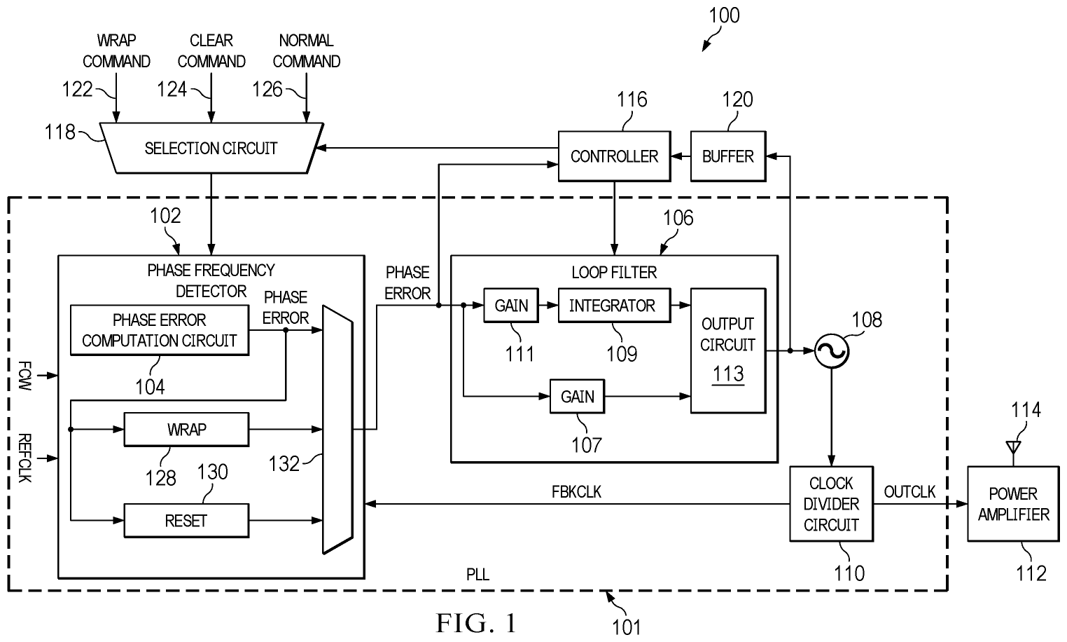

FIG. 1 is a block diagram of an example circuit 100 including a PLL 101, a controller 116, and a selection circuit 118. The PLL 101 includes a phase frequency detector (PFD) 102 with a phase error computation circuit 104, a loop filter 106, and an oscillator 108. The PLL 101 can also include a divider circuit 110. In some examples, the PLL 101 is a radio frequency (RF) PLL. In some examples the PLL 101 is an RF All Digital PLL (ADPLL), and accordingly, the phase frequency detector 102 produces a digital phase error signal, the loop filter 106 performs functions such as digital gain and/or integration on the digital phase error signal, and the oscillator 108 has a digital control interface. While the disclosed examples refer to RF ADPLLs, the examples disclosed herein can also apply to any type of PLL and associated regulation loop.

As illustrated in FIG. 1, the PFD 102 receives a feedback clock signal (FBKCLK), a reference clock signal (REFCLK), and a frequency control word signal (FCW). In some examples, the PFD 102 is a mixed analog and digital phase detector and comprises both analog and digital components. The PFD 102 includes a phase error computation circuit 104 that generates one or more phase error signals based on the timing relationship between the feedback clock signal and the reference clock signal. In an example, the frequency control word specifies a number of cycles of the feedback clock signal expected per cycle of the reference clock signal, and for each cycle of the reference clock, the phase error computation circuit 104 may provide, via the phase error signal, a count of actual cycles of the feedback clock signal and/or a difference between actual cycles and expected cycles of the feedback clock signal based on the frequency control word.

The PFD 102 includes a phase error selection circuit 132 (e.g., a multiplexer) that couples the phase error computation circuit 104 to the loop filter 106 to provide the phase error signal from the phase error computation circuit 104 to the loop filter 106. The loop filter 106 may apply one or more functions to the phase error signal to produce a set of oscillator control signals for the oscillator 108. In an example, the loop filter 106 includes a first path (e.g., a proportional path) that includes a first gain circuit 107 that applies a first gain to the phase error signal and a second path (e.g., an integral path) that includes a second gain circuit 111 that applies a second gain to the phase error signal and an integrator 109 (e.g., an accumulator) coupled to the second gain circuit 111 that integrates the output of the second gain circuit 111 over a number of cycles of the reference clock signal. The loop filter 106 may also include an output circuit 113 configured to provide the set of oscillator control signals based on a function of the first gain circuit 107 and the second gain circuit 111 (e.g., based on a sum of the outputs of the first gain circuit 107 and the second gain circuit 111). Thus, the output of the first path reacts immediately to changes in the phase error, and in contrast, the second path may not be as responsive and may have a lower gain. Given a properly settled loop, when the current phase error is zero or close to zero, the loop filter output may be mainly governed by the second path, as the product of the current phase error and the first gain in the first path is close to zero.

In some examples, the phase error computation circuit 104 does not integrate the FCW of the control signal and instead, the phase error computation circuit 104 differentiates estimates of the feedback clock phase to produce frequency estimates. In some such examples, to compute the phase error, the phase error computation circuit 104 compares the FCW of the control signal with the estimated frequency to produce the frequency error. The phase error computation circuit 104 then integrates the resulting frequency error to get the phase error signal.

The oscillator 108 receives the oscillator control signals from the loop filter 106. The oscillator 108 may include a digital controlled oscillator, a voltage controlled oscillator, a current controlled oscillator, and/or any other type of oscillator. In some examples, the oscillator 108 is an analog circuit component. The oscillator 108 generates an oscillator output clock signal under the control of the loop filter 106 that may be a sinusoidal signal whose frequency closely matches a center frequency determined based on the REFCLK and the frequency control word provided to the PFD 102.

In some examples, the oscillator 108 is coupled to a clock divider circuit 110 that produces an output clock signal (OUTCLK) that is divided down from the oscillator output clock. The oscillator 108 may also include one or more signal buffers to drive the output clock signal to circuits outside of the PLL 101.

The clock divider circuit 110 may also produce the feedback clock signal FBKCLK for the PFD 102 by dividing down the oscillator output clock, and in some examples, the output clock signal and the feedback clock signal have the same frequency. Thus, the PFD 102 can compare the phase and frequency of the feedback clock signal FBKCLK from the oscillator 108 to the reference clock signal REFCLK. Accordingly, such feedback loop allows for the PLL 101 to continually monitor and correct any phase and frequency difference between the feedback clock signal FBKCLK and an ideal clock based on the reference clock signal REFCLK and the FCW. The PLL 101 may respond to any difference by adjusting the operation of the oscillator 108 to maintain the lock.

In some examples, the divider circuit 110 is an analog circuit component.

The divider circuit 110 and buffers of the PLL 101 may provide the output clock to any suitable circuit, and in some examples, the PLL 101 is coupled to a transmitter signal chain that includes a power amplifier 112, which in turn is coupled to an antenna 114. In some examples, the power amplifier 112 is an analog circuit component.

As explained above, the PLL 101 can experience disturbances, which, if unchecked, may produce overshoot, undershoot, instability, or other undesirable responses in the output clock signal. These events may occur during phase acquisition, in response to step responses, other rapid changes in inputs or outputs, and/or other situations. For example, an input step response may occur when a control signal (e.g., the FCW) specifies a change in the desired frequency of the output clock signal from the PLL 101. On the output side, a step response may occur based on a change in the load such as a sudden presence of pulling from the power amplifier 112, which may affect oscillator gain and thereby require higher or lower control values from the loop filter 106 to produce the specified output frequency.

To avoid these types of disturbances creating an undesirable response in the frequency of the output clock signal, the circuit 100 may detect a disturbance based on a change in the phase error, and the PLL 101 may respond by adjusting the phase error provided to the loop filter 106. The PLL 101 may also alter the behavior of the loop filter 106 by, for example, adjusting one or more of the gains applied by the loop filter 106 or reverting the integrator 109 to a previous loop filter output value. These corrective actions may help the PLL 101 settle faster by reducing the amplitude of any output frequency undershoot and/or overshoot.

As illustrated in FIG. 1, the PFD 102 of the PLL 101 is coupled to a controller 116. The controller 116 receives a phase error signal from the PFD 102, which in some examples, is the same phase error signal provided to the loop filter 106. The controller 116 also receives control signals and/or configuration signals from external devices, which may be used to select a response to a disturbance. When the phase error signal indicates the disturbance, the controller may implement the response by providing a selection control signal to a selection circuit 118 that controls the PFD 102 and/or providing a filter control signal to the loop filter 106.

As described above, during operation of the PLL 101, the controller 116 may monitor the phase error signal for behaviors in the phase error that may produce an undesirable response in the frequency of the output clock and thus indicate a disturbance. In some examples, the controller 116 detects a disturbance by comparing the phase error specified by the phase error signal to a threshold and/or comparing a behavior of the phase error specified by the phase error signal over a set of cycles of the reference clock signal to a pattern (e.g., a phase error exceeding a threshold for a given number of cycles, a phase error monotonically increasing for a given number of cycles, a phase error signal monotonically increasing for a given number of cycles then decreasing, etc.).

Accordingly, in some examples, the controller 116 detects a peak in phase error magnitude where the phase error signal monotonically increases for a given number of cycles of the reference clock signal then decreases. In some examples, the controller 116 detects the time of the peak in phase error magnitude with a time resolution given by the reference clock signal. In many examples, disturbances such as a step response are most likely to cause a change in output clock frequency and/or phase when the frequency of the output clock signal from the PLL 101 is approximately correct.

The controller 116 is not limited to any specific implementation for phase error behavior detection. The phase error behavior detection can be performed by hardware, software, and/or a combination thereof. The behavior detection may be configured or controlled by any of the following: a control signal to enable the search for some or all of the phase error behaviors that indicate a disturbance; a configurable error threshold that phase error magnitude needs to exceed before the search for a phase error behavior is enabled; a configurable number of cycles of the reference clock signals that the phase error needs to exhibit a behavior (rising, falling, remaining substantially the same), and/or a limit on a number of behavior detection events to respond to per activation of the search, which may avoid phase error modifications outside the time window of interest. The phase error behavior detection can also support an optional phase error sample qualification before a search for a particular behavior of the phase error can trigger a response.

Upon detecting behavior indicating a disturbance, such as a peak in phase error magnitude, the controller 116 may select a response to improve PLL 101 performance by reducing settling time, reducing overshoot and/or undershoot, and/or other suitable improvements. A selected response may include a corrective action such as modifying the phase error and/or operation of the loop filter 106. Accordingly, based on which response is selected, the controller 116 causes commands to be provided that cause the PFD 102 and/or the loop filter 106 to perform the selected response.

With respect to the PFD 102, the controller 116 may implement a particular response by causing a selection circuit 118 to propagate a command and/or set of parameters to the PFD 102 based on the response. The selection circuit 118 is coupled to the controller 116 and to the PFD 102. The selection circuit 118 may receive a selection control signal from the controller 116 and a set of commands and/or parameters associated with different responses, including in some examples, to continue the current operation of the PLL 101. Thus, the selection circuit 118 may receive commands and parameters associated with a wrap command 122, a clear command 124, or a command 126 to continue normal operation (e.g., the current operating mode prior to the disturbance). These are described at more detail below. However, the wrap command 122 causes a large phase error to be reduced by measuring phase error relative to a closer REFCLK edge. The clear command 124 re-initializes the current phase reference. The normal command 126 corresponds to the PFD 102 and the loop filter 106 performing in the same manner as prior to the disturbance.

In some examples, the selection circuit 118 includes a multiplexer that receives the commands and/or parameters associated with the wrap command 122, the clear command 124, the normal command 126, and/or other suitable response commands. The controller 116 provides a selection control signal to the multiplexer, and the multiplexer outputs a selected set of commands and/or parameters via an output coupled to the PFD 102 based on the selection control signal from the controller 116.

In some examples, instead of the selection circuit 118 being separate from the controller 116, the controller 116 includes the selection circuit 118 as a part of the controller 116. In such examples, the controller 116 provides the commands and/or parameters to the PFD 102 that correspond to a selected response such as: the wrap command 122, the clear command 124, and the normal command 126. Accordingly, the controller 116 indicates to the PFD 102 whether to and how to modify the operations of the PFD 102.

With respect to the wrap response, the wrap command 122 may cause the phase error selection circuit 132 to cause wrap logic 128 in the PFD 102 to provide a modified phase error to the loop filter 106 and/or the controller 116 that is different from the phase error determined by the phase error computation circuit 104. In particular, the modified phase error may be made smaller by measuring relative to a nearer REFCLK edge. In examples where the phase error and the modified phase error specify a number of cycles of FBKCLK more or less than expected, this may have the effect of limiting the modified phase error to between −0.5 cycles and 0.5 cycles.

In some examples, the wrap logic 128 causes the modified phase error to be whichever of the measured phase error minus the floor of the measured phase error or the measured phase error minus the ceiling of the measured phase error has the lesser magnitude. For example, a measured phase error of −2.4 may produce a modified phase error of −0.4 (e.g., −2.4-ceiling (−2.4)), and a measured phase error of 2.7 may produce a modified phase error of-0.3 (e.g., 2.7-ceiling (2.7)). Thus, wrapping the measured phase error may not change the overall relationship between the feedback clock signal FBKCLK and the reference clock signal REFCLK, and the wrapping of the phase error maintains the phase reference between the feedback clock signal FBKCLK and the reference clock signal REFCLK.

The wrap response may also include changes to the loop filter 106, and in some examples, the controller 116 provides a command that causes a change to the value being output by the integrator 109. For example, to ensure that the modified phase error causes minimal change in the loop filter output, the controller 116 may provide a control signal that causes the integrator 109 to set the output of the integrator 109 to a previous value output by the loop filter 106 minus a function of the modified phase error. For example:

$$integrator ( n ) = loop\_filter \_output ( n - 1 - k ) - Kp ⋆ wrapped\_phase \_error ( n )$$

where integrator (n) represents the current output of the integrator 109, loop_filter_output(n-1-k) represents a previous output of the loop filter 106, k is a configurable parameter, Kp represents a proportional gain (e.g., the gain applied by gain circuit 107), and wrapped_phase_error(n) represents the current modified phase error provided by the PFD 102.

Thus, in the example, the output of the loop filter 106 may be represented as:

$$loop\_filter \_output ( n ) = integrator ( n ) + Kp ⋆ wrapped\_phase \_error ( n )$$

where loop_filter_output (n) represents the current output of the loop filter 106, integrator (n) represents the current output of the integrator 109, Kp represents a proportional gain (e.g., the gain applied by gain circuit 107), and wrapped_phase_error (n) represents the current modified phase error provided by the PFD 102. This simplifies to:

$$loop\_filter \_output ( n ) = loop\_filter \_output ( n - 1 - k )$$

With respect to the clear response, the clear command 124 may cause the phase error selection circuit 132 to cause the reset logic 130 in the PFD 102 to provide a modified phase error to the loop filter 106 and/or the controller 116 that is different from the phase error determined by the phase error computation circuit 104. In particular, the modified phase error may be set to an initial or startup value, a random value, or a value indicating no error. In examples where the phase error and the modified phase error specify a number of cycles of FBKCLK more or less than expected, this may have the effect of setting the modified phase error to zero.

The clear response may also include changes to the loop filter 106, and in some examples, the controller 116 causes a change to the value being output by the integrator 109. For example, to avoid the modified phase error causing a step in the loop filter output, the controller 116 provides a control signal that causes the integrator 109 to set the output of the integrator 109 to a previous value output by the loop filter 106. The age of the previous loop filter 106 value may be selectable. For example:

$$integrator ( n ) = loop\_filter \_output ( n - 1 - k )$$

where integrator(n) represents the current output of the integrator 109, loop_filter_output(n-1-k) represents a previous output of the loop filter 106, and k is a configurable parameter.

Thus, in the example where the modified phase error is zero, the output of the loop filter may be represented as:

$$loop\_filter \_output ( n ) = loop\_filter \_output ( n - 1 - k )$$

where loop_filter_output (n) represents the current output of the loop filter 106, loop_filter_output(n-1-k) represents the previous output of the loop filter 106, and k is a configurable parameter.

The clear response may be useful in systems, devices, and/or events that do not require known or maintained phase references, such as devices using non-coherent modulation to transfer information (e.g., Bluetooth low energy), or initial phase lock acquisition.

With respect to the normal response, the normal command 126 may cause the PFD 102 continue to operate in the same manner despite the disturbance. Thus, the PFD 102 may provide the phase error measured by the phase error computation circuitry 104 (instead of a modified phase error) to the loop filter 106 and/or the controller 116. The normal command 126 may cause the loop filter 106 to apply one or more functions (e.g., a weight and/or a weighted integral) to the phase error signal to produce the set of oscillator control signals for the oscillator 108.

The PFD 102 includes other components (not illustrated), such as registers, counters, mathematical operators, and other logic components, to facilitate the operations of the PFD 102, the phase error computation circuit 104, the wrap logic 128, and the reset logic 130. In some examples, the wrap logic 128 and reset logic 130 perform operations upon the phase error signal coming from the phase error computation circuit 104, and the PFD 102 uses the phase error selection circuit 132 and the output of the selection circuit 118 (MUX output) to select between 1) the unmodified phase error signal from the phase error computation circuit 104, 2) the output of the wrap logic 128, and 3) the output of the reset logic 130 to provide as the output of the PFD 102 to the loop filter 106 and/or the controller 116.

In an example, the selection circuit provides the first input, the unmodified phase error signal from the phase error computation circuit 104 under most operating conditions, except for limited intervals (e.g., a single cycle) where the output of the wrap logic 128 or the output of the reset logic 130 is provided. After such an interval, the output of the phase error selection circuit 132 may be set back to the unmodified phase error signal from the phase error computation circuit 104, although the phase error signal from the phase error computation circuit 104 will be based, at least in part, on the phase error when the corrective action was taken. For example, if the phase error was 3, and a clear command was issued, then the phase error provided by the phase error computation circuit 104 in the next cycle after the clear command may be 0 or close to zero. Similarly, following a wrap command, future phase error values provided by the phase error computation circuit 104 may include the impact of the corrective action.

In some examples, the circuit 100 includes a buffer 120 coupled to the loop filter 106 and to the controller 116. The buffer 120 receives loop filter outputs from the loop filter 106 and stores the loop filter outputs. The buffer 120 can provide historical loop filter outputs based on the size of the buffer 120 to either the controller 116 or to the loop filter 106. In some examples, the controller 116 can instruct the buffer 120 to provide a particular loop filter output to the loop filter 106 or to the controller 116 from the stored loop filter outputs based on the configuration information in the controller 116.

In some examples, the buffer 120 provides the loop filter outputs to the controller 116 as needed by the controller 116. The size of the buffer 120 can be predetermined or can be determined by the controller 116 based on the control signals and/or configuration signals CTL/CFG from external devices sent to the controller 116. In some examples, the controller 116 retrieves the loop filter outputs from the buffer 120 and transmits the loop filter outputs to the loop filter 106, as needed.

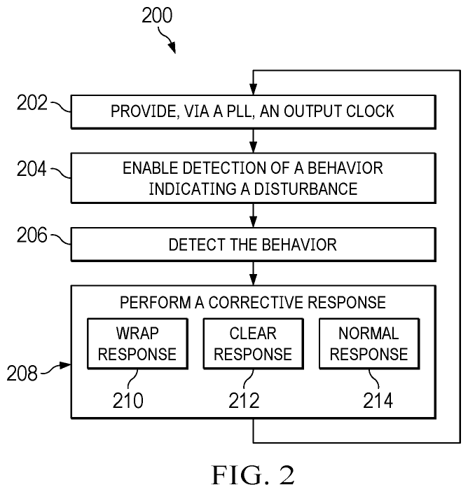

FIG. 2 is a flowchart illustrating the operations 200 of the circuit 100 of FIG. 1. As mentioned previously, some disturbances, if uncorrected, may cause unwanted transients in the output clock. Thus, the controller 116 of the circuit 100 of FIG. 1 may cause the PLL 101 to make a corrective response to improve settling time and reduce the magnitude of the output variation.

Referring to block 202, the circuit 100 may utilize a PLL 101 to provide an output clock signal (e.g., OUTCLK) based on a reference clock signal (e.g., REFCLK). In some examples, this includes an initial (e.g., open-loop) phase that includes resetting a phase error of a phase error signal to an initial value, providing the phase error signal to a loop filter 106, and providing a set of oscillator control signals from the loop filter 106 to an oscillator 108. In some such examples, a clock divider 110 is used to divide down an output of the oscillator 108 to provide OUTCLK.

Providing the output clock signal may also include another (e.g., closed-loop) phase that follows the initial phase. In this phase, the clock divider 110 may provide a feedback clock signal (e.g., FBKCLK) by dividing down the output of the oscillator. A PFD 102 may receive the FBKCLK, REFCLK, and a frequency control word that specifies a number of cycles of the feedback clock signal expected per cycle of the reference clock signal. During this phase, the phase error signal may be based on a comparison of the FBKCLK to the REFCLK in light of the frequency control word instead of being set to the initial value. The loop filter 106 may apply one or more functions (e.g., a weight and/or a weighted integral) to the phase error signal to determine the set of oscillator control signals that adjust the frequency of the oscillator 108 based on this phase error signal until the desired timing of the OUTCLK is achieved.

Referring to block 204, the controller 116 enables detection of a behavior pattern that indicates a disturbance. In an example, the controller 116 enables detection of a phase error exceeding a threshold for a given number of cycles, a phase error monotonically increasing for a given number of cycles, and/or a phase error signal monotonically increasing for a given number of cycles then decreasing.

Referring to block 206, the controller 116 detects the behavior. This may include selecting a response to the behavior.

Referring to block 208, the controller 116 causes the PLL 101 to perform a corrective response to the disturbance indicated by the behavior. Examples of corrective responses include a wrap response as in block 210, a clear response as in block 212, and a normal response as in block 214.

The wrap response of block 210 may include causing wrap logic 128 in the PFD 102 to make a correction to the normal phase error determined by the phase error computation circuit 104, so that PFD 102 provides a modified phase error to the loop filter 106 and/or the controller 116 that is different from the phase error determined by the phase error computation circuit 104 in the normal operating mode. In particular, the modified phase error may be made smaller by measuring relative to a nearer REFCLK edge, such as described above. The wrap response may also include the controller 116 causing a change to the value being output by the loop filter 106. This may include causing the integrator 109 to set the output of the integrator 109 to a previous value output by the loop filter 106 minus a function of the modified phase error, such as described above.

The clear response of block 212 may include causing reset logic 130 in the PFD 102 to make a correction to the normal phase error determined by the phase error computation circuit 104, so that PFD 102 provides a modified phase error to the loop filter 106 and/or the controller 116 that is different from the phase error determined by the phase error computation circuit 104 in the normal operating mode. In particular, the modified phase error may be set to an initial or startup value, a random value, or a value indicating no error, such as described above. The clear response may also include the controller 116 causing a change to the value being output by the loop filter 106. This may include causing the integrator 109 to set the output of the integrator 109 and the output of the loop filter 106 to a previous value output by the loop filter 106, such as described above.

The normal response of block 214 may include causing the PFD 102 to provide the phase error measured by the phase error computation circuitry 104 (instead of a modified phase error) to the loop filter 106 and/or the controller 116. The normal response may also include the controller 116 causing the loop filter 106 to continue to apply the same functions (e.g., a weight and/or a weighted integral) to the phase error signal to produce the set of oscillator control signals for the oscillator 108.

Execution may then return to block 202.

As mentioned, the disclosed examples herein enable faster settling time when a disturbance is encountered with reduced overshoot and/or undershoot compared to what is expected for a certain loop bandwidth. Accordingly, reducing phase error settling time and frequency overshoot and/or undershoot in response to, for example, power amplifier pulling, yields less frequency drift from the PLL settling process caused by, in this example power amplifier ramping. Further, less frequency drift enables devices to broadcast shorter tones before transmitting preambles for some communication protocols (e.g., Bluetooth Low Energy), which reduces energy consumption.

The controllers described herein (e.g., controller 116) can be implemented as generic or custom controllers (e.g., coupled to a non-transitory memory) and configured to execute instructions stored in such memory. For example, the controllers can include one or more, generic or custom, integrated circuits (ICs) (e.g., application-specific integrated circuits (ASICs)), logic circuits, microprocessors, field programmable gate arrays (FPGAs) that may instantiate instructions, central processor units (CPUs), graphic processor units (GPUs), digital signal processors (DSPs). In some examples, the processors can include dedicated or general purpose circuitry, and the various processors may be combined or may be discrete circuitry.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Modifications are possible in the described embodiments, and other embodiments are possible, within the scope of the claims.

Unless otherwise stated, “about,” “approximately,” or “substantially” preceding a value means +/−10 percent of the stated value.

While the foregoing is directed to specific examples, other and further examples may be devised without departing from the basic scope thereof, and the scope thereof is determined by the claims that follow.

What is claimed is:

1. A circuit comprising:
a phase frequency detector configured to determine a phase error;
a loop filter coupled to the phase frequency detector and configured to provide a clock control signal based on the phase error; and
a controller coupled to the phase frequency detector and to the loop filter, the controller configured to:
receive the phase error;
detect a behavior of the phase error; and
responsive to the behavior of the phase error, perform a response that includes:
causing the phase frequency detector to adjust the phase error; and
causing the loop filter to adjust the clock control signal.

2. The circuit of claim 1, wherein the causing of the phase frequency detector to adjust the phase error includes causing the phase frequency detector to determine the phase error by limiting a measured phase error to a range.

3. The circuit of claim 2, wherein the range is between-0.5 periods and 0.5 periods.

4. The circuit of claim 2, wherein the adjusted phase error is whichever of the measured phase error minus a floor of the measured phase error or the measured phase error minus a ceiling of the measured phase error has a lesser magnitude.

5. The circuit of claim 1, wherein:
the loop filter includes an integrator; and
the causing of the loop filter to adjust the clock control signal includes setting an output of the integrator to a previous value of the clock control signal minus a function of the phase error.

6. The circuit of claim 1, wherein the causing of the phase frequency detector to adjust the phase error includes causing the phase frequency detector to set the phase error to a predetermined value.

7. The circuit of claim 6, wherein the predetermined value is zero.

8. The circuit of claim 1, wherein:
the loop filter includes an integrator; and
the causing of the loop filter to adjust the clock control signal includes setting an output of the integrator to a previous value of the clock control signal.

9. The circuit of claim 1, wherein the controller is configured to select the response from among a set of responses.

10. The circuit of claim 1, wherein the behavior includes one of: the phase error exceeding a threshold for a given duration, the phase error monotonically increasing for a given duration, or the phase error monotonically increasing for a given duration then decreasing.

11. A circuit comprising:
a phase locked loop circuit that includes:
a phase frequency detector configured to:
receive a reference clock and a feedback clock; and
determine a phase error based on the reference clock and the feedback clock;
a loop filter coupled to the phase frequency detector and configured to provide a clock control signal based on the phase error; and
an oscillator coupled to the loop filter and configured to provide a clock signal based on the clock control signal, wherein the feedback clock is based on the clock signal, and wherein the phase locked loop circuit is configured to provide an output clock based on the clock signal; and
a controller coupled to the phase locked loop circuit and configured to:
receive the phase error;
detect a behavior of the phase error; and
responsive to the behavior of the phase error, perform a response that includes:
causing the phase frequency detector to adjust the phase error; and
causing the loop filter to adjust the clock control signal.

12. The circuit of claim 11, wherein the response includes causing the phase frequency detector to wrap the phase error to a nearest clock edge.

13. The circuit of claim 11, wherein the response includes causing the phase frequency detector to adjust the phase error by limiting a measured phase error to a range.

14. The circuit of claim 13, wherein the response includes causing the phase frequency detector to adjust the phase error based on whichever of the measured phase error minus a floor of the measured phase error or the measured phase error minus a ceiling of the measured phase error has a lesser magnitude.

15. The circuit of claim 11, wherein:
the loop filter includes an integrator; and
the response includes setting an output of the integrator to a previous value of the clock control signal minus a function of the phase error.

16. The circuit of claim 11, wherein the response includes causing the phase frequency detector to set the phase error to a predetermined value.

17. The circuit of claim 16, wherein the predetermined value is zero.

18. The circuit of claim 11, wherein:
the loop filter includes an integrator; and
the response includes setting an output of the integrator to a previous value of the clock control signal.

19. The circuit of claim 11, wherein the controller is configured to select the response from among a set of responses.

20. The circuit of claim 11, wherein:
the phase locked loop circuit includes a clock divider coupled to the oscillator and to the phase frequency detector; and
the clock divider is configured to provide the feedback clock and the output clock based on the clock signal of the oscillator.

21. The circuit of claim 11, wherein the phase frequency detector is configured to:
receive a frequency control word; and
determine the phase error further based on the frequency control word.

22. A method comprising:
receiving a phase error with respect to a reference clock and a feedback clock, wherein:
the phase error is determined by a phase frequency detector; and
the feedback clock is generated based on an output of a loop filter;
detecting whether a behavior of the phase error is present; and
based on whether the behavior is present, determine whether to perform a response that includes:
causing the phase frequency detector to adjust the phase error; and
causing the loop filter to adjust the output of the loop filter.

23. The method of claim 22 further comprising performing the response, wherein the response includes causing the phase frequency detector to adjust the phase error by limiting a measured phase error to a range.

24. The method of claim 23, wherein the adjusted phase error is whichever of the measured phase error minus a floor of the measured phase error or the measured phase error minus a ceiling of the measured phase error has a lesser magnitude.

25. The method of claim 22 further comprising performing the response, wherein:
the loop filter includes an integrator; and
the response includes setting an output of the integrator to a previous value of the output of the loop filter minus a function of the phase error.

26. The method of claim 22 further comprising performing the response, wherein the response includes causing the phase frequency detector to set the phase error to a predetermined value.

27. The method of claim 22 further comprising performing the response, wherein:
the loop filter includes an integrator; and
the response includes setting an output of the integrator to a previous value of the output of the loop filter.

28. The method of claim 22 further comprising:
selecting the response from among a set of responses; and
performing the response.

29. The method of claim 22, wherein the behavior includes at least one of: the phase error exceeding a threshold for a given duration, the phase error monotonically increasing for a given duration, or the phase error monotonically increasing for a given duration then decreasing.
